(19) United States
(12) Patent Application Publication
(10) Pub. No.: US 2011/0133266 A1
(43) Pub. Date: Jun. 9, 2011

(54) Flash Memory Having a Floating Gate in the Shape of a Curved Section

(76) Inventors: Sanh Tang, Boise, ID (US); Krishna K. Parat, Palo Alto, CA (US); Haitao Liu, Meridian, ID (US)

(21) Appl. No.: 12/629,992

(22) Filed: Dec. 3, 2009

(51) Int. Cl. H01L 29/788; H01L 21/28

(52) U.S. Cl. 257/316; 438/593; 257/E29.3; 257/E21.209; 977/938

(57) ABSTRACT

The floating gate of a flash memory may be formed with a flat lower surface facing a substrate and a curved upper surface facing the control gate. In some embodiments, such a device has improved capacitive coupling to the control gate and reduced capacitive coupling to its neighbors.

### BACKGROUND

This relates generally to flash memories.

Flash memories are semiconductor memories that have a floating gate and a control gate overlying the floating gate. The accumulation of charge on the floating gate may be controlled by the control gate to program the cell into one of at least two states.

Particularly as device sizes become ever smaller, capacitive coupling between adjacent gates in an array of memory elements becomes an increasingly important issue. Capacitive coupling results in slower device speeds. Generally, one advantage of size reduction is cost reduction, but, another advantage is typically an improvement in speed. Thus, gate coupling may become a larger problem with decreasing gate size and decreasing spacing between floating gates of adjacent memory cells.

### BRIEF DESCRIPTION OF THE DRAWINGS

FIG. 1 is an enlarged, cross-sectional view of one embodiment of the present invention at an early stage of manufacture;

FIG. 2 is an enlarged, cross-sectional at a subsequent stage in accordance with one embodiment;

FIG. 3 is an enlarged, cross-sectional view at a subsequent stage to that shown in FIG. 2 in accordance with one embodiment;

FIG. 4 is an idealized cross-sectional view of one embodiment of the present invention;

FIG. 5a is a cross-sectional view of one embodiment of the present invention taken generally along the line 5-5 in FIG. 4;

FIG. 5b is a cross-sectional view taken generally along the line 5-5 in FIG. 4 in a different embodiment of the present invention; and

FIG. 6 is a depiction of an early stage of manufacture for one embodiment.

### DETAILED DESCRIPTION

In accordance with some embodiments, capacitive coupling between a floating gate and a control gate may be improved or at least maintained, while reducing capacitive coupling between neighboring floating gates. As a result, in some embodiments, as size scales downwardly, adverse capacitive coupling effects may be reduced, improving performance. Particularly, in memory technologies below 30 nanometers, the principles described herein may become increasingly important.

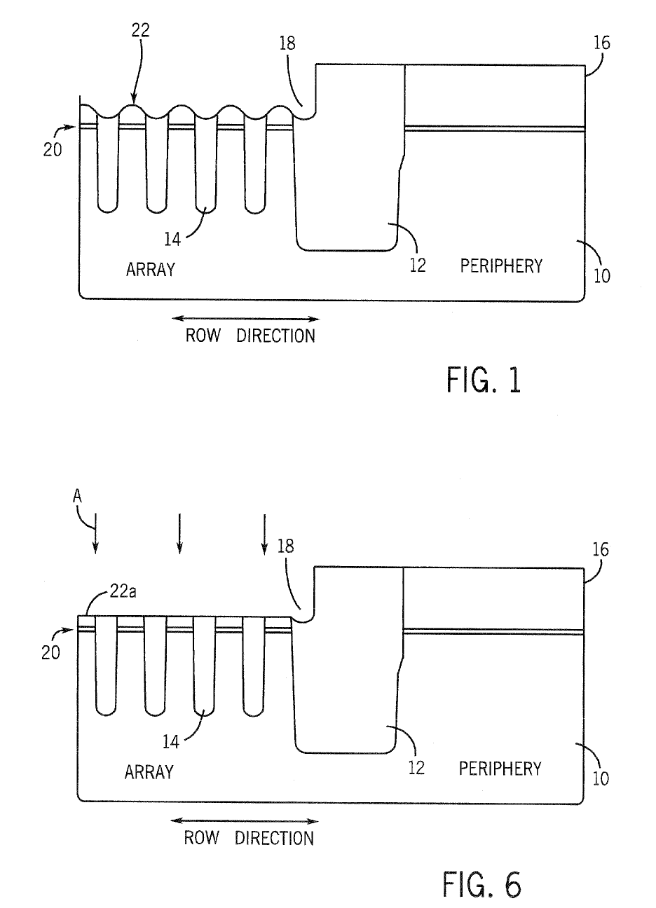

Referring to FIG. 1, a flash memory at an early stage of manufacture may include a substrate 10 of any conventional material. In some embodiments, a shallow trench isolation 12 is formed between a poly gate 16 for a logic, control or periphery circuit (marked “periphery”) and a region to the left thereof in FIG. 1 where the memory cells make up a memory array (marked “array”). In some embodiments, the isolation may include a notch 18.

Each cell site in the array may be comprised, at this stage, of a floating gate electrode 22, which may be made of any conventional material. Between adjacent cell sites, may be shallow trench isolations 14. In one embodiment, the floating gates 22 extend into the page which corresponds, in this embodiment, generally to the direction of the bitlines or columns in the finished device. The floating gates 22 may be formed over a gate dielectric 20 which may be formed of any dielectric.

Thus, in some embodiments, the floating gates 22 are unsegmented at this stage. However, in other embodiments, the floating gates 22 have already been segmented and may be dots having generally comparable widths and lengths, each floating gate 22 dot already being associated with a separate and distinguishable cell area.

In accordance with some embodiments of the present invention, the floating gates 22 have a curved upper surface. This curved upper surface may be effective in reducing capacitive coupling between one gate and its neighbors, at least in the “row direction” in FIG. 1. In some embodiments, at this stage, the floating gates 22 have a cylindrical upper surface. In general, the upper surface of the floating gates constitute a curved section. By “section”, it is intended to refer to a portion of a curved, closed shape. Examples of closed shapes include spheres, cylinders and elliptical solids. Each of these curved sections includes a flat or planar lower surface which is situated over the substrate 10. Between the flat or planar lower surface and the substrate 10 may be a gate dielectric 20.

A variety of different curved shapes may be used for the curved section of the floating gate. A portion of a cylinder, a hemisphere, or elliptical solid may be used, as may any other curved shape in which a central portion of the floating gate is thicker than its edges, at least in one dimension, be it the bitline or word line dimension (perpendicular to the row direction in FIG. 1 and into the page). In some embodiments, reduced thickness edges may be present completely around the floating gate in all directions, in which case the floating gate is a hemispherical section.

In some embodiments, the floating gate 22 may have an aspect ratio that is advantageous in terms of effectively coupling to the yet to be deposited control gate, while reducing capacitive coupling to its floating gate neighbors. In some embodiments, aspect ratios (e.g. height to width in the row direction) of from 1 to 4 to 4 to 2 may be advantageous. However, the aspect ratio range may also be obtained in the column direction.

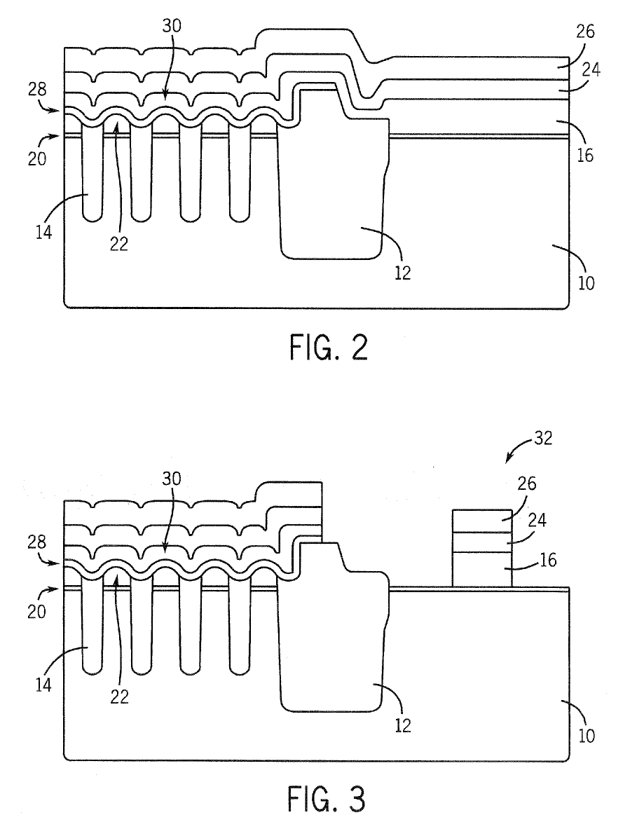

Referring next to FIG. 2, at this point, an interlayer dielectric 28 has been deposited, while in the periphery, to the right side of the shallow trench isolation 12, the dielectric 28 is removed, at least in part. The interlayer dielectric may be any suitable material including oxide/nitride/oxide (ONO). The interlayer dielectric 28 has a plurality of curved sections conforming to the floating gates 22.

Next, a control gate layer 30 that forms the control gate is deposited over the array on the left side of the shallow trench isolation 12, while a thicker poly layer 16 was previously deposited outside the array. In one embodiment polysilicon may be used for the layers 30 and 16. Like the dielectric 28, the control gate layer 30 also includes matching curved sections that follow the curvature of the floating gates. A word line 24 may be deposited and patterned into elongate stripes, extending, in some embodiments, in the row direction transverse to the lengths of the floating gates 22. The layer 26 may be a suitable dielectric layer.

The word lines, once they have been patterned, may be used as a mask to segment the floating gates 22 into discrete segments for each cell in one embodiment. In such an embodiment, the floating gates then have the curved upper surface, shown in FIG. 2, but having flat ends opposed in the direction of the bitlines or column lines. In other embodiments, such as where the floating gate is segmented before depositing the word line 24, the floating gate may be curved in all directions, including both the word line and bitline directions. This may reduce capacitive coupled in the row and column directions.

Next, as shown in FIG. 3, the structures in the periphery are patterned to form the transistor 32, while the array side is masked.

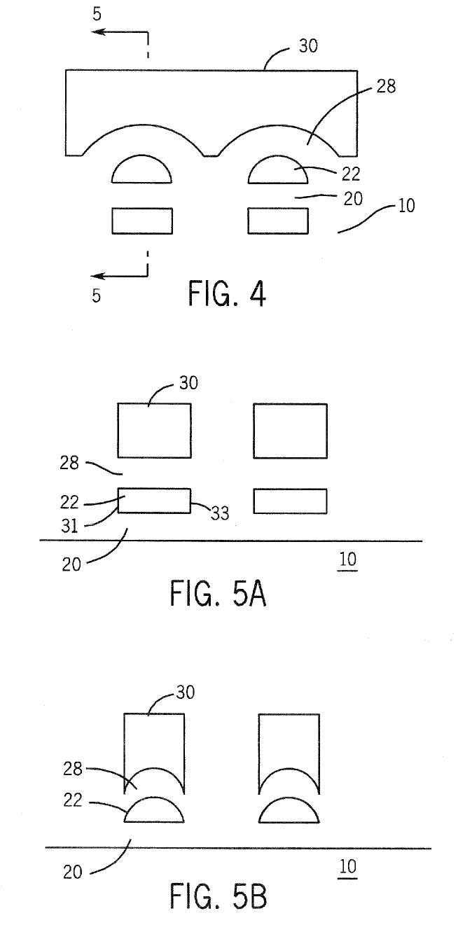

Now, referring to FIG. 4, because of the curvature of the floating gate 22 upper surface, the area of coupling between the floating gate and the control gate 30 is increased. This is a result of the fact that the curved surface of the floating gate has a longer extent than a corresponding conventional flat upper surface floating gate. At the same time, because of the lower edge profile (e.g. in the row direction), the capacitive coupling to neighbors may be reduced.

Referring to FIG. 5a, in one embodiment, the floating gate, singulated in the column direction, has flat vertical ends 31 and 33. This may be the result of depositing parallel strips of rectangular material to form the gates and then etching to round the upper gate surface, prior to gate singulation.

In contrast, in accordance with another embodiment, shown in FIG. 5b, the floating gate upper surface is curved in both the row and column directions and, in some embodiments, may be curved around its entire periphery. Such an embodiment may experience reduced capacitive coupling, both in the row and column directions. In some cases, an extra masking step may be needed to fabricate such a device.

The formation of the curved upper surface floating gate may begin with a conventional rectangular solid floating gate strips 22a, shown in FIG. 6, which are then exposed to a plasma etch “A” with physical sputtering to round the edges, as shown in FIG. 1. As one skilled in the art would understand, by using a slightly isotropic etch, one can get greater etching around the periphery than is the case with a purely anisotropic etch. Among the ways to make the etch more isotropic includes using more argon or more pressure. Other techniques may be used as well.

The embodiments of the present invention may be used in connection with both NOR type flash memories and NAND type flash memories. The techniques described herein are applicable to any semiconductor device with overlapping electrodes wherein it is desirable to increase the capacity of coupling between the vertically overlapped electrodes, while reducing capacitive coupling to lateral neighbors.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a flash memory floating gate having a curved surface facing a control gate and a substantially flat surface facing an underlying substrate.

2. The method of claim 1 including forming the floating gate in a shape that increases the capacitive coupling to the control gate while reducing the capacitive coupling to neighboring floating gates relative to a rectangular floating gate.

3. The method of claim 1 including forming the floating gate with an aspect ratio of from one to four to four to two.

4. The method of claim 1 including forming an interlayer dielectric between the floating gate and the control gate, said interlayer dielectric having a curved lower surface and a curved upper surface.

5. The method of claim 1 including forming a control gate having a curved lower surface facing the floating gate.

6. The method of claim 1 including forming the floating gate by etching a rectangular gate to have a curved upper surface.

7. The method of claim 1 including forming a cylindrical floating gate.

8. The method of claim 1 including forming a hemispherical floating gate.

9. The method of claim 1 including forming the floating gate of a curved section.

10. The method of claim 1 including forming a gate having a feature size of less than 30 nanometers.

11. A flash memory comprising:
a substrate;
a floating gate over said substrate, said floating gate having a generally planar surface facing said substrate; and
a control gate over said floating gate, said floating gate having an upper surface that is a curved section facing said control gate.

12. The memory of claim 11 wherein said curved section is cylindrical.

13. The memory of claim 11 wherein said curved section is hemispherical.

14. The memory of claim 11 wherein said memory is a NOR flash memory.

15. The memory of claim 11 wherein said floating gate has an aspect ratio of from one to four to four to two.

16. The memory of claim 11 including an interlayer dielectric between said floating gate and said control gate, said interlayer dielectric having a curved lower surface and a curved upper surface.

17. The memory of claim 11 wherein said control gate has a curved lower surface facing said floating gate and matching the curvature of said floating gate.

18. The memory of claim 11 wherein said floating gate has a feature size of less than 30 nanometers.

19. The memory of claim 11 wherein said floating gate has a pair of opposed parallel end faces.

20. A method comprising:
depositing a substantially rectangular strip of material to form a floating gate;
exposing said strip to an etching process to produce a curved upper surface on said floating gate; and
forming a flash memory using said floating gate.

21. The method of claim 20 wherein said surface is curved to reduce capacitive coupling to adjacent floating gates.

22. The method of claim 20 including curving an overlying control gate so as to increase the capacitive coupling between said control gate and said floating gate relative to a planar floating gate upper surface.

23. The method of claim 20 including forming a control gate and a floating gate having facing curved surfaces, the curved surface of said control gate generally matching the curved surface of said floating gate.

24. The method of claim 20 including shaping said floating gate so as to increase the area of the floating gate opposed to an overlying control gate.

25. The method of claim 24 including reducing the thickness of the edges of said floating gate to reduce capacitive coupling to adjacent floating gates.

26. The method of claim 20 including forming said floating gate so it is thicker in the center than at the edges.

27. The method of claim 26 including forming said floating gate with an aspect ratio of from one to four to four to two.
